(19) United States
(12) Patent Application Publication
(10) Pub. No.: US 2024/0421192 A1
(43) Pub. Date: Dec. 19, 2024

(54) SILICON CARBIDE DEVICE WITH SINGLE METALLIZATION PROCESS FOR OHMIC AND SCHOTTKY CONTACTS

(71) Applicant: Woflspeed, Inc., Durham, NC (US)

(72) Inventors: Rahul R. POTERA, Apex, NC (US); Neal OLDHAM, Apex, NC (US)

(21) Appl. No.: 18/211,429

(22) Filed: Jun. 19, 2023

(51) Int. Cl. H01L 29/16; H01L 29/06; H01L 29/45; H01L 29/47; H01L 29/66; H01L 29/872

(52) U.S. Cl. CPC H01L 29/1608; H01L 29/0619; H01L 29/45; H01L 29/47; H01L 29/66068; H01L 29/872

(57) ABSTRACT

A method of forming a semiconductor device includes providing a first layer including silicon carbide having a first conductivity type, and forming a plurality of doped regions having a second conductivity type in the silicon carbide layer. A second layer including nickel is provided on the first layer and contacts the plurality of doped regions and the first layer. The first layer and the second layer are annealed at a first anneal temperature to form a layer of nickel silicide on the first layer. The first layer and the layer of nickel silicide are annealed at a second anneal temperature that is greater than first anneal temperature to cause the layer of nickel silicide to form ohmic junctions to the plurality of doped regions and to form a Schottky barrier junction to the first layer.

### BACKGROUND

The present disclosure relates to semiconductor device structures and in particular to silicon carbide semiconductor devices including both ohmic and Schottky contacts.

Narrow bandgap semiconductor materials, such as silicon (Si) and gallium arsenide (GaAs), are widely used in semiconductor devices for low power and, in the case of Si, low frequency applications. However, these semiconductor materials may not be well-suited for high power and/or high frequency applications, for example, due to their relatively small bandgaps (1.12 eV for Si and 1.42 for GaAs at room temperature) and relatively small breakdown voltages.

Interest in high power, high temperature and/or high frequency applications and devices has focused on wide bandgap semiconductor materials such as silicon carbide (3.2 eV for 4H-SiC at room temperature) and the Group III nitrides (e.g., 3.36 eV for GaN at room temperature). These materials may have higher electric field breakdown strengths and higher electron saturation velocities than GaAs and Si.

One important application for wide bandgap semiconductors such as silicon carbide is in Schottky diodes.

A Schottky diode, also known as Schottky barrier diode, is a semiconductor diode formed by the junction of a semiconductor with a metal. The metal-semiconductor junction (instead of a semiconductor-semiconductor junction as in conventional PN-junction diodes) in a Schottky diode creates a Schottky barrier. The metal side acts as the anode, and an n-type semiconductor acts as the cathode of the diode. When sufficient forward voltage is applied to overcome the Schottky barrier of the metal-semiconductor junction, current flows through the device in the forward direction. When a reverse voltage is applied, a depletion region is formed in the semiconductor, obstructing current flow.

Compared to a conventional PN-junction diode, a Schottky diode has a low forward voltage drop and a very fast switching action.

An important difference between a PN-junction diode and a Schottky diode is the reverse recovery time (tᵣᵣ), which is the time it takes for the diode to switch from a conducting (forward biased) state to a non-conducting (reverse biased) state. In the conducting state, a conventional PN-junction diode injects minority carriers into the diffusion region on the N-side of the junction where they recombine with majority carriers after diffusion. The reverse recovery time of a PN-junction is primarily limited by the diffusion capacitance of minority carriers accumulated in the diffusion region during the conducting state.

In contrast, a Schottky diode is a unipolar or “majority carrier” device that does not rely on minority carrier injection. Rather, in the conducting state, majority carriers (electrons in the case of an n-type semiconductor layer) are injected across the junction. Thus, switching a Schottky diode from a conducting to a non-conducting state does not require time for recombination of the injected carriers. Rather, the switching speed of a Schottky diode is only limited by the junction capacitance of the device.

Silicon carbide Schottky diodes are the rectifiers of choice in advanced power electronics at 650V and above, primarily because they achieve fast switching speeds with much lower leakage current and capacitance than silicon-based Schottky diodes.

Schottky diodes may also be monolithically integrated with other types of devices, such as metal-oxide semiconductor field effect transistor (MOSFET) devices.

### SUMMARY

A method of forming a semiconductor device according to some embodiments includes providing a first layer, the first layer comprising silicon carbide and having a first conductivity type, and forming a plurality of doped regions in the silicon carbide layer. The plurality of doped regions have a second conductivity type opposite the first conductivity type. A second layer is provided on the first layer. The second layer includes nickel, and contacts the plurality of doped regions and the first layer. The method further includes annealing the first layer and the second layer at a first anneal temperature to form a layer of nickel silicide on the first layer, and annealing the first layer and the layer of nickel silicide at a second anneal temperature that is greater than first anneal temperature. Annealing the first layer and the layer of nickel silicide at the second anneal temperature causes the layer of nickel silicide to form ohmic junctions to the plurality of doped regions and to form a Schottky barrier junction to the first layer.

The first anneal temperature may be less than about 700 C, and the second anneal temperature may be greater than about 800 C. In some embodiments, the second anneal temperature is between about 825 C and 925 C.

The first conductivity type may be n-type and the second conductivity type may be p-type.

The plurality of doped regions may include implanted regions in the first layer.

The first layer may have a doping concentration of less than about 2E16 cm-3. The plurality of doped regions may have a doping concentration greater than about 2E19 cm-3. The plurality of doped regions may include junction barrier Schottky regions in the first layer.

The semiconductor device may include a Schottky diode and/or a metal-oxide semiconductor field effect transistor.

A method of forming a metal contact on a first layer according to further embodiments is provided. The first layer includes silicon carbide having a first conductivity type, and the method includes forming a doped region in the first layer, the doped region having a second conductivity type opposite the first conductivity type, forming a layer of nickel silicide on the first layer, wherein the layer of nickel silicide contacts the first layer and contacts the doped region, and annealing the layer of nickel silicide and the first layer at a sufficient temperature to cause the layer of nickel silicide to form an ohmic contact to the doped region and a Schottky barrier junction to the first layer.

In some embodiments, the layer of nickel silicide and the first layer are annealed at an anneal temperature greater than about 800 C, and in some embodiments between about 825 C and 925 C.

The first conductivity type may be n-type and the second conductivity type may be p-type.

The doped region may include implanted regions in the first layer.

The first layer may have a doping concentration of less than about 2E16 cm-3. The doped region may have a doping concentration greater than about 2E19 cm-3. The doped region may include a junction barrier Schottky region in the first layer.

The semiconductor device may include a Schottky diode and/or a metal-oxide semiconductor field effect transistor.

A semiconductor device structure according to some embodiments includes a first layer of silicon carbide having a first conductivity type, and a plurality of doped regions in the first layer. The plurality of doped regions have a second conductivity type opposite the first conductivity type. The semiconductor device structure further includes a layer of nickel silicide on the first layer. The layer of nickel silicide forms ohmic junctions to the plurality of doped regions and forms a Schottky barrier junction to the silicon carbide layer.

The first layer may have a doping concentration of less than about 2E16 cm-3, and the plurality of doped regions may have a doping concentration greater than about 2E19 cm-3.

The semiconductor device structure may be a Schottky diode and/or a metal-oxide semiconductor field effect transistor.

The ohmic junctions to the plurality of doped regions may have resistivities of about 2 mohm-cm2 or less. The Schottky barrier junction to the silicon carbide layer may have a barrier height of between about 1.4 eV and 1.7 eV and/or may have an ideality factor of about 1.15 or less.

### BRIEF DESCRIPTION OF THE DRAWINGS

FIG. 1A illustrates a Schottky diode according to some embodiments.

FIG. 1B illustrates a monolithically integrated MOSFET and Schottky diode according to some embodiments.

FIGS. 2A to 2H illustrate operations for forming a Schottky diode in accordance with some embodiments.

FIG. 3 is a graph of current versus voltage for a Schottky contact formed according to some embodiments.

FIG. 4 is a flowchart illustrating operations according to some embodiments.

FIGS. 5A and 5B illustrate horizontal Schottky diode structures according to some embodiments.

### DETAILED DESCRIPTION OF EMBODIMENTS

Embodiments of the inventive concepts will now be described in connection with the accompanying drawings.

Some embodiments provide methods of forming SiC-based Schottky diodes, and devices with integrated SiC-based Schottky diodes, using the same metallization process to form both a Schottky contact and one or more other contacts to the device, such as an ohmic contact, which may simplify the fabrication process.

Some embodiments may reduce the number of required mask operations and/or other steps needed to fabricate the device.

A SiC junction barrier Schottky (JBS) semiconductor device includes an n− SiC drift layer on an n-type SiC substrate. An anode, or positive, contact is formed on the drift layer and a cathode, or negative, contact is formed on the substrate. The anode contact forms a rectifying Schottky junction with the drift layer. A plurality of heavily doped p-type junction barrier regions are formed at the surface of the drift layer. The anode contact makes ohmic contact to the junction barrier regions. In normal forward bias operation, conduction is through the Schottky junction, while in reverse bias, a depletion region formed by P-N junctions between the junction barrier regions and the drift layer protects the Schottky junction from high electric fields. The P-N junctions between the junction barrier regions and the drift layer may turn on to provide additional current handling capability under surge conditions.

A conventional anode contact for a SiC JBS device may form both a Schottky junction to the n− drift layer of the device and an ohmic junction to p+ junction barrier regions in the drift layer. However, in conventional approaches, the Schottky junction to the drift layer is typically optimized, while the anode contact makes a sub-optimal ohmic contact to p+ junction barrier regions in the drift layer. Such an approach may undesirably limit the P-N junctions between the junction barrier regions and the drift layer from turning on at a low surge current. An alternative approach is to use two separate metallization processes for the anode contact—one for the Schottky contact to the n− drift layer and one for the ohmic contacts to the junction barrier regions. In that approach, both contacts can be optimized, but additional time and expense is required to perform two separate metallization processes.

In contrast, some embodiments described herein provide a single metallization process that can simultaneously form a high-quality Schottky contact to n− silicon carbide and a high-quality ohmic contact to p+ silicon carbide.

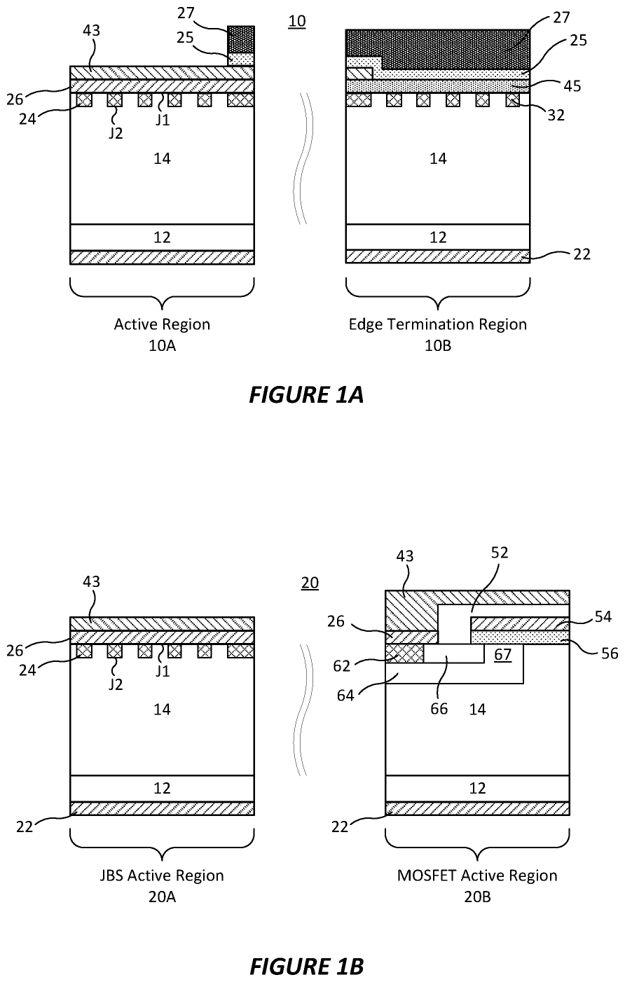

A SiC Schottky diode 10 according to some embodiments is illustrated in FIG. 1A. The Schottky diode 10 includes an active region 10A and an edge termination region 10B (also called a junction termination region, or simply a termination region). Although the active region 10A and the edge termination region 10B are shown in FIG. 1A as separate regions for ease of illustration, it will be appreciated that they are part of the same device.

An n− silicon carbide epitaxial layer 14 is formed on an n-type silicon carbide substrate 12. The n− silicon carbide epitaxial layer 14, which acts as the drift layer of the device, may be doped with n-type dopants, such as nitrogen or phosphorus, at a doping concentration of less than about 2E16 cm-3. A metal silicide contact 26 is formed on the surface of the silicon carbide epitaxial layer 14 opposite the substrate 12. The metal silicide contact 26, which corresponds to the anode of the device, forms a first Schottky barrier junction J1 with portions of the silicon carbide epitaxial layer 14 in between the junction barrier regions 24. A metal overlayer 43 is formed on the metal silicide contact 26.

A plurality of junction barrier regions 24 are provided at the surface of the silicon carbide epitaxial layer 14. The junction barrier regions 24 are regions of p+ silicon carbide formed by implantation of p-type dopant atoms, such as aluminum, into the silicon carbide epitaxial layer 14. The junction barrier regions 24 may have a doping concentration of greater than about 2E19 cm-3. The metal silicide anode contact 26 contacts the junction barrier regions 24 and forms ohmic junctions (i.e., ohmic contact) with the junction barrier regions 24. The junction barrier regions 24 form P-N junctions J2 with the silicon carbide epitaxial layer 14.

The metal silicide anode contact 26 may include nickel silicide. As explained in more detail below, a nickel silicide layer may be formed in such a manner that it can simultaneously form a high-quality Schottky barrier junction to the lightly doped n− silicon carbide epitaxial layer 14 and a low resistance ohmic contact to a p+ silicon carbide region, such as the heavily doped junction barrier regions 24. For example, the metal silicide contact 26 may form a Schottky barrier junction to the silicon carbide epitaxial layer 14 having a barrier height greater than about 1.4 eV and ohmic junctions to the junction barrier regions 24 having resistivities less than about 2 mohm-cm2. In some embodiments, the Schottky barrier junction J1 between the metal silicide contact 26 and the silicon carbide epitaxial layer 14 may have a barrier height between about 1.4 eV and 1.7 eV, for example about 1.6 eV. In some embodiments, the ohmic junctions to the junction barrier regions 24 may have resistivities of about 1 mohm-cm2.

In some embodiments, the Schottky barrier junction J1 between the metal silicide contact 26 and the silicon carbide epitaxial layer 14 may have an ideality factor less than 1.15, for example 1.05. The ideality factor (also known as the quality factor or the emission factor) of a Schottky junction is a measure of the deviation from ideal behavior. It provides information about the efficiency and imperfections of the junction. In an ideal Schottky diode, the ideality factor is equal to 1, indicating perfect behavior according to the Shockley equation. However, in real devices, various imperfections can cause deviations from ideal behavior. These imperfections include interface states, barrier inhomogeneities, surface defects, and recombination processes.

The Schottky barrier junction J1 between the metal silicide contact 26 and the silicon carbide epitaxial layer 14 has a lower barrier energy than the P-N junction J2 between the junction barrier regions 24 and the silicon carbide epitaxial layer 14. This allows the first Schottky barrier junction J1 to turn on before the P-N junction J2 in the forward biased (conducting) state. Conversely, in the reverse biased (non-conducting) state, the first Schottky barrier junction J1 is shielded from high electric fields by the depletion region formed at the P-N junction J2.

A cathode ohmic contact 22 is formed on the back side of the substrate 12.

In the edge termination region 10B, a plurality of floating guard rings 32 (also called equipotential rings or field rings) are formed as p+ implanted regions at the surface of the silicon carbide epitaxial layer 14. A field oxide layer 45 is on silicon carbide epitaxial layer 14 in the edge termination region 10B. A silicon nitride passivation layer 25 is formed on the field oxide layer and extends onto the anode contact 26 and the metal overlayer 43 in the active region 10A. A protective layer 27 of a material such as polyimide is formed on the silicon nitride passivation layer 25.

FIG. 1B illustrates a monolithically integrated MOSFET and Schottky diode device 20 according to some embodiments. The device 20 includes a JBS active region 20A and a MOSFET active region 20B. The JBS active region 20A is similar to the active region 10A of the SiC Schottky diode 10 shown in FIG. 1A. The device 20 also includes an edge termination region (not shown), similar to the edge termination region 10B shown in FIG. 1A, surrounding the JBS active region 20A and the MOSFET active region 20B.

Referring to FIG. 1B, the device 20 includes a p-well region 64 and an implanted p+ contact region 62 in the epitaxial layer 14. An n+ source region 66 is formed in the p-well region 64 adjacent the p+ contact region 62, and defines a channel region 67 at the surface of the p-well region 64. A gate insulator 56 is formed on the epitaxial layer 14 above the channel region 67, and a gate contact 54 is formed on the gate insulator 56. The gate contact may include a metal or other conductive material, such as polysilicon. An interlayer dielectric layer 52 is formed over the gate structure, and the metal overlayer 43 extends onto the interlayer dielectric layer 52.

The anode nickel silicide contact 26 extends onto the MOSFET active region 20B and acts as a source contact for the device 20. The anode nickel silicide contact 26 forms an ohmic contact to both the p+ contact region 62 and the n+ source region 66.

For example, the metal silicide contact 26 may form a Schottky barrier junction to the silicon carbide epitaxial layer 14 having a barrier height greater than about 1.4 eV and ohmic junctions to the junction barrier regions 24 and the p+ contact region 62 having resistivities less than about 2 mohm-cm2. In some embodiments, the Schottky barrier junction between the metal silicide contact 26 and the silicon carbide epitaxial layer 14 may have a barrier height between about 1.4 eV and 1.7 eV, for example about 1.6 eV. In some embodiments, the ohmic junctions to the junction barrier regions 24 and the p+ contact region 62 may have resistivities of about 1 mohm-cm2.

In some embodiments, the Schottky barrier junction between the metal silicide contact 26 and the silicon carbide epitaxial layer 14 may have an ideality factor less than 1.15, for example 1.05.

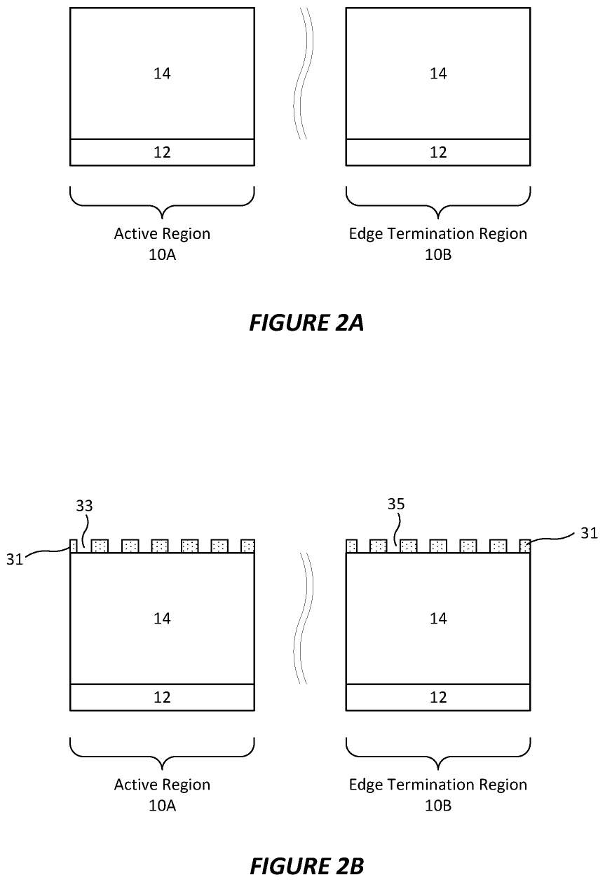

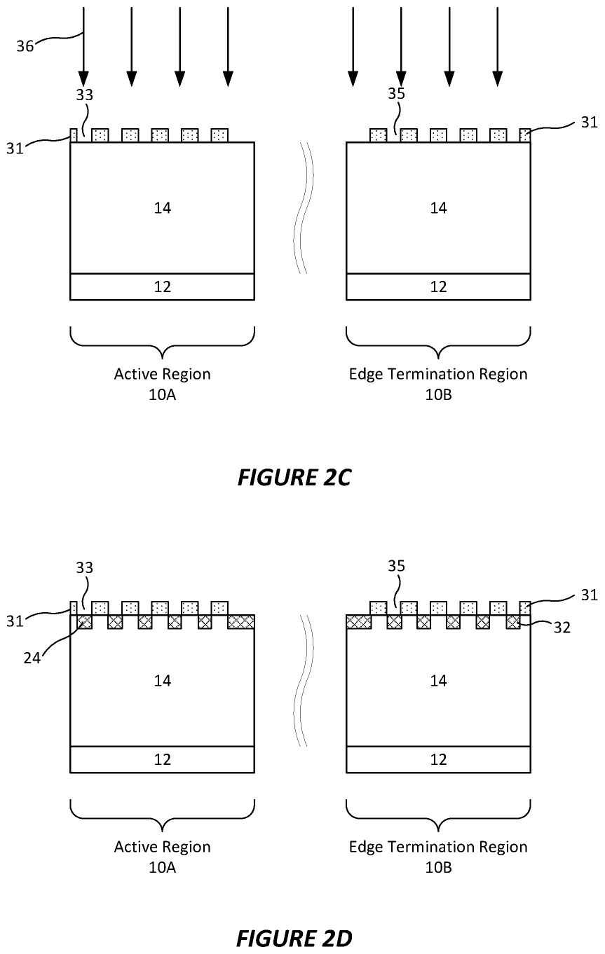

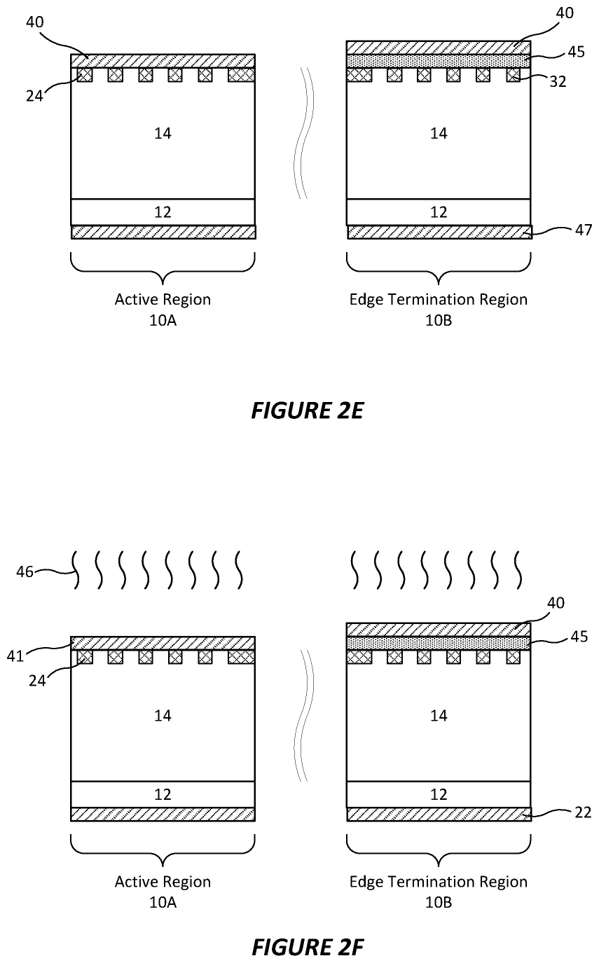

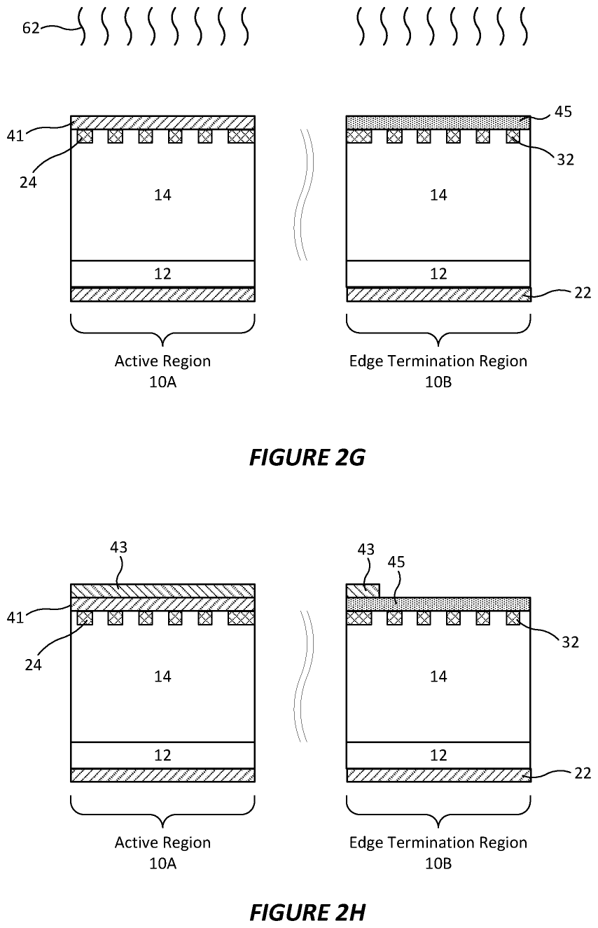

FIGS. 2A to 2H illustrate operations for forming a Schottky diode in accordance with some embodiments. It will be appreciated that similar operations may be used in the fabrication of other types of devices, such as integrated Schottky diode-MOSFET devices.

Referring to FIG. 2A, a silicon carbide substrate 12 is provided. The silicon carbide substrate 12 may have a 2H, 4H, 6H or 3C polytype, and may have an off-angle orientation of about 0 to 5 degrees. A silicon carbide epitaxial layer 14 is formed on the substrate 12. The substrate 12 and epitaxial layer 14 are divided into an active region 10A and an edge termination region 10B, which may surround the active region 10A. The silicon carbide substrate 12 and the epitaxial layer 14 are doped with first conductivity type dopants, e.g., n-type dopants, such as nitrogen and/or phosphorus. The epitaxial layer 14 is lightly doped, with a net doping concentration of less than about 2E16 cm-3.

Referring to FIG. 2B, an implant mask 31 is formed on the epitaxial layer 14. The mask 31 is patterned to form openings 33 in the active region 10A and openings 35 in the edge termination region 10B.

Referring to FIG. 2C, second conductivity dopants 36, e.g., p-type dopants such as boron and/or aluminum, are implanted through the openings 33, 35 in the implant mask 31 to form junction barrier regions 24 in the active region 10A and floating guard rings 32 in the edge termination region 10B, as shown in FIG. 2D. The junction barrier regions 24 and the floating guard rings may by highly doped regions having a net doping concentration of about 2E19 cm-3 or greater. The implanted dopants may be activated using a conventional anneal process.

Referring to FIG. 2E, a field oxide layer 45 is formed on the silicon carbide epitaxial layer 14 in the edge termination region 10B. A layer of nickel 40 is blanket deposited on the structure, and contacts the epitaxial layer 14 in the active region 10A.

A backside metal layer 47 may also deposited onto the bottom of the substrate 12 at this time. The backside metal layer 47 may be a metal such as nickel that forms a silicide. In some embodiments, the backside metal may include tantalum and/or titanium.

Referring to FIG. 2F, a silicidation anneal 46 is performed by using a rapid thermal anneal to heat the structure to a temperature of about 600° C. to about 700° C., and in some cases at least about 650° C., to form a metal silicide layer 41 on the silicon carbide epitaxial layer 14 in the active region 10A. The silicidation anneal 46 may also cause the metal layer 47 on the back side of the substrate 12 to form a metal silicide layer 41.

Referring to FIG. 2G, non-silicided portions of the metal layer 40 may be stripped from the epitaxial layer 14, leaving the metal silicide layer 41 of the epitaxial layer 14 in the active region 10A. The metal silicide layer contacts the junction barrier regions 24 and portions of the epitaxial layer 14 between the junction barrier regions 24.

A high temperature anneal 62 is then performed on the structure at a temperature of about 850° C. to 900° C., which can cause the metal silicide layer 41 to form a first Schottky junction J1 with the epitaxial layer 14 and to form ohmic contacts to the junction barrier regions 24. The anneal 62 can also cause the metal silicide layer 22 on the back side of the substrate 12 to form an ohmic contact with the n-type silicon carbide substrate 12.

Referring to FIG. 2H, a metal overlayer 43 is formed on the metal silicide layer 41 in the active region 10A, and may partially extend onto the field oxide layer 45 in the edge termination region 10B. The metal overlayer 43 may include nickel, titanium, molybdenum, titanium and/or tungsten.

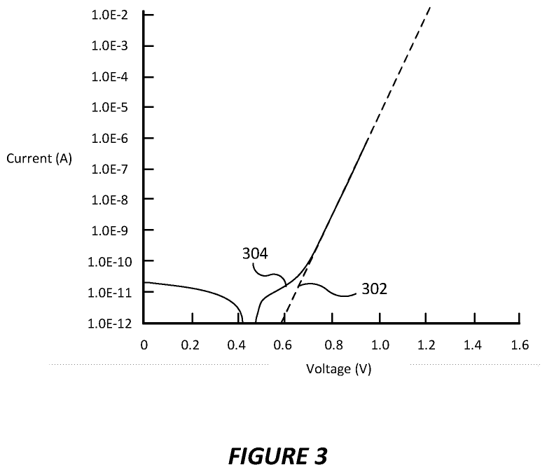

FIG. 3 is a graph that illustrates current as a function of voltage for a SiC Schottky junction formed with a nickel silicide anode contact according to some embodiments. The graph in FIG. 3 shows model 302 and measured 304 I-V curves for a NiSi-SiC Schottky junction formed on a SiC layer having a net n-type doping concentration of about 1E16 cm-3 using a contact anneal at 645 C. As shown in FIG. 3, a SiC Schottky junction formed with a nickel silicide anode contact may have a barrier height of about 1.6 eV and an ideality factor of about 1.05. These figures indicate that a high-quality NiSi-SiC Schottky junction can be formed on formed on a n− SiC layer.

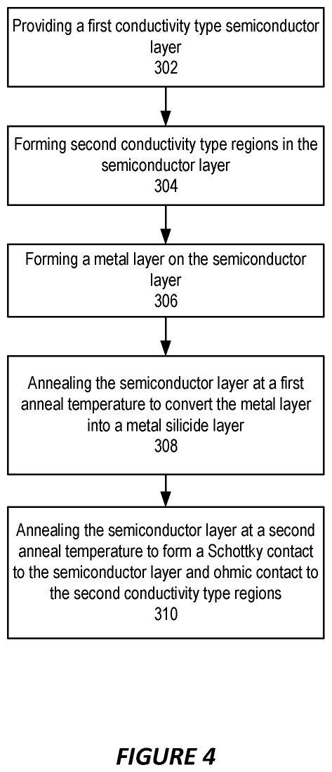

FIG. 4 illustrates operations of forming a semiconductor device according to some embodiments. Referring to FIG. 4, a method of forming a semiconductor device according to some embodiments includes providing a silicon carbide layer having a first conductivity type (block 402). The silicon carbide layer may have a doping concentration of less than about 2E16 cm-3.

A plurality of second conductivity type regions are formed in a surface of the silicon carbide layer (block 404). The second conductivity type regions may have a doping concentration of greater than about 2E19 cm-3, and may be junction barrier regions in the silicon carbide layer.

A layer of nickel is formed on the silicon carbide layer (block 406). The layer of nickel contacts the plurality of second conductivity type regions and the layer of nickel contacts the silicon carbide layer in regions between the plurality of second conductivity type regions.

The layer of nickel is then annealed at a first anneal temperature to form a layer of nickel silicide (block 408). The first anneal temperature may be less than about 700 C, and in some embodiments may be between about 620 C and 680 C, and in some embodiments between about 640 C and 660 C. In some embodiments, the first anneal temperature may be about 650 C. Finally, the layer of nickel silicide is annealed at a second anneal temperature that is greater than first anneal temperature, to cause the layer of nickel silicide to form ohmic junctions to the plurality of second conductivity type regions and to form a Schottky barrier junction to the silicon carbide layer. The second anneal temperature may be greater than about 800 C. In some embodiments, the second anneal temperature may be between about 825 C and 925 C.

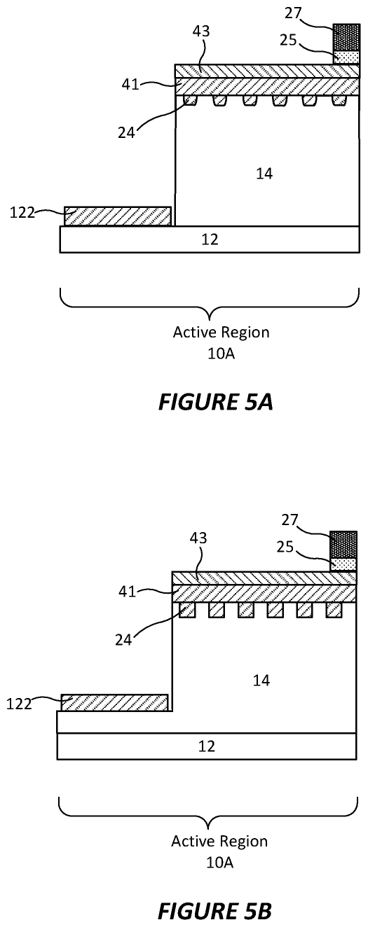

Alternative Schottky diode structures according to some embodiments is illustrated in FIGS. 5A and 5B. As shown therein, in some embodiments, a cathode ohmic contact 122 may be formed to an exposed portion of the substrate 12 (FIG. 5A), or to an exposed portion of the epitaxial layer 14 on the front side of the epitaxial layer 14 opposite the substrate 12 (FIG. 5B). In embodiments in which the cathode ohmic contact 122 is formed to an exposed portion of the epitaxial layer 14, it will be appreciated that the exposed portion of the epitaxial layer may be implanted with dopant ions to increase the doping concentration thereof prior to forming the cathode ohmic contact 122.

It will be understood that, although the ordinal terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Furthermore, relative terms, such as “lower” or “bottom” and “upper” or “top,” may be used herein to describe the relationship of one element to another as illustrated in the drawings. It is understood that relative terms are intended to encompass different orientations of the device in addition to the orientation depicted in the drawings. For example, if the device in one of the drawings is turned over, features described as being on the “lower” side of an element would then be oriented on “upper” side of that element. The exemplary term “lower” can therefore describe both lower and upper orientations, depending of the particular orientation of the device. Similarly, if the device in one of the drawings is turned over, elements described as “below” or “beneath” other elements would then be oriented above those other elements. The exemplary terms “below” or “beneath” can therefore describe both an orientation of above and below.

The terminology used in the description of the disclosure herein is for the purpose of describing particular embodiments only and is not intended to be limiting of the disclosure. As used in the description of the disclosure and the appended claims, the singular forms “an” and “the” are intended to include the plural forms as well, unless the context clearly indicates otherwise. It is also understood that the term “and/or” as used herein refers to and encompasses any and all possible combinations of one or more of the associated listed items. It will be further understood that the terms “comprises” and “comprising,” when used in this specification, specify the presence of stated steps, operations, features, elements, and/or components, but do not preclude the presence or addition of one or more other steps, operations, features, elements, components, and/or groups thereof.

Embodiments of the disclosure are described herein with reference to cross-section illustrations that are schematic illustrations of idealized embodiments of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. The regions illustrated in the drawings are schematic in nature, and their shapes are not intended to illustrate the actual shape of a region of a device and are not intended to limit the scope of the disclosure unless explicitly stated otherwise. Further, lines that appear straight, horizontal, or vertical in the below drawings for schematic reasons will often be sloped, curved, non-horizontal, or non-vertical. Further, while the thicknesses of elements are meant to be schematic in nature.

Unless otherwise defined, all terms used in disclosing embodiments of the disclosure, including technical and scientific terms, have the same meaning as commonly understood by one of ordinary skill in the pertinent art and are not necessarily limited to the specific definitions known at the time of the present disclosure. Accordingly, these terms can include equivalent terms that are created after such time. It is further understood that terms, such as those defined in commonly used dictionaries, should be interpreted as having a meaning that is consistent with their meaning in the present specification and in the context of the relevant art.

Although embodiments of the inventive concepts have been described in considerable detail with reference to certain configurations thereof, other versions are possible. Accordingly, the spirit and scope of the invention should not be limited to the specific embodiments described above.

What is claimed is:

1. A method of forming a semiconductor device, comprising:
providing a first layer, the first layer comprising silicon carbide and having a first conductivity type;
forming a plurality of doped regions in the silicon carbide layer, the plurality of doped regions having a second conductivity type opposite the first conductivity type;
providing a second layer on the first layer, wherein the second layer comprises nickel, and wherein the second layer contacts the plurality of doped regions and contacts the first layer;
annealing the first layer and the second layer at a first anneal temperature to form a layer of nickel silicide on the first layer;
annealing the first layer and the layer of nickel silicide at a second anneal temperature that is greater than first anneal temperature, to cause the layer of nickel silicide to form ohmic junctions to the plurality of doped regions and to form a Schottky barrier junction to the first layer.

2. The method of claim 1, wherein the first anneal temperature is less than about 700 C.

3. The method of claim 2, wherein the second anneal temperature is greater than about 800 C.

4. The method of claim 3, wherein the second anneal temperature is between about 825 C and 925 C.

5. The method of claim 1, wherein the first conductivity type is n-type and wherein the second conductivity type is p-type.

6. The method of claim 1, wherein the plurality of doped regions comprise implanted regions in the first layer.

7. The method of claim 1, wherein the first layer has a doping concentration of less than about 2E16 cm-3.

8. The method of claim 1, wherein the plurality of doped regions have a doping concentration greater than about 2E19 cm-3.

9. The method of claim 1, wherein the plurality of doped regions comprise junction barrier Schottky regions in the first layer.

10. The method of claim 1, wherein the semiconductor device comprises a Schottky diode and/or a metal-oxide semiconductor field effect transistor.

11. A method of forming a metal contact on a first layer, the first layer comprising silicon carbide having a first conductivity type, the method comprising:
forming a doped region in the first layer, the doped region having a second conductivity type opposite the first conductivity type;
forming a layer of nickel silicide on the first layer, wherein the layer of nickel silicide contacts the first layer and contacts the doped region; and
annealing the layer of nickel silicide and the first layer at a sufficient temperature to cause the layer of nickel silicide to form an ohmic contact to the doped region and a Schottky barrier junction to the first layer.

12. The method of claim 11, wherein annealing the layer of nickel silicide and the first layer comprises annealing the layer of nickel silicide at an anneal temperature greater than about 800 C.

13. The method of claim 12, wherein the anneal temperature is between about 825 C and 925 C.

14. The method of claim 11, wherein the first conductivity type is n-type and wherein the second conductivity type is p-type.

15. The method of claim 11, wherein the first layer has a doping concentration of less than about 2E16 cm-3.

16. The method of claim 11, wherein the doped region has a doping concentration greater than about 2E19 cm-3.

17. The method of claim 11, wherein forming the layer of nickel silicide on the first layer comprises forming a layer of nickel on the first layer and annealing the layer of nickel to form nickel silicide.

18. The method of claim 17, wherein the layer of nickel is annealed to form nickel silicide at a lower temperature than the layer of nickel silicide is annealed to form the ohmic contact to the doped region and the Schottky barrier junction to the first layer.

19. A semiconductor device structure, comprising:
a first layer, wherein the first layer comprises silicon carbide and has a first conductivity type;
a plurality of doped regions in the first layer, the plurality of doped regions having a second conductivity type opposite the first conductivity type; and
a layer of nickel silicide on the first layer, wherein the layer of nickel silicide forms ohmic junctions to the plurality of doped regions and forms a Schottky barrier junction to the silicon carbide layer.

20. The semiconductor device structure of claim 19, wherein the first layer has a doping concentration of less than about 2E16 cm-3.

21. The semiconductor device structure of claim 19, wherein the plurality of doped regions have a doping concentration greater than about 2E19 cm-3.

22. The semiconductor device structure of claim 19, wherein the semiconductor device comprises a Schottky diode and/or a metal-oxide semiconductor field effect transistor.

23. The semiconductor device structure of claim 19, wherein the ohmic junctions to the plurality of doped regions have resistivities of about 2 mohm-cm2 or less.

24. The semiconductor device structure of claim 19, wherein the Schottky barrier junction to the silicon carbide layer has a barrier height of between about 1.4 eV and 1.7 eV.

25. The semiconductor device structure of claim 19, wherein the Schottky barrier junction to the silicon carbide layer has an ideality factor of about 1.15 or less.
